(19) United States
(12) Patent Application Publication
(10) Pub. No.: US 2026/0090436 A1
(43) Pub. Date: Mar. 26, 2026

(54) METHOD FOR MANUFACTURING SEMICONDUCTOR DEVICE

(71) Applicant: United Microelectronics Corp., Hsinchu (TW)

(72) Inventors: Chiao-Yi TENG, Taichung City (TW); Yang-Ju LU, Changhua County (TW); Chih-Yueh LI, Taipei City (TW); Wei-Xin GAO, Tainan City (TW); Hsiang-Chi CHIEN, Pingtung County (TW)

(21) Appl. No.: 18/942,826

(22) Filed: Nov. 11, 2024

(30) Foreign Application Priority Data
Sep. 25, 2024 (TW) 113136385

(51) Int. Cl. H01L 23/00

(52) U.S. Cl. CPC H10W 72/00; H10W 72/019; H10W 72/01951; H10W 72/01971; H10W 72/90; H10W 72/923; H10W 72/9415; H10W 90/792

(57) ABSTRACT

A method for manufacturing a semiconductor device is provided. The method includes the following steps. First, a first semiconductor structure and a second semiconductor structure are provided. The first semiconductor structure includes a first conductive pillar and a first conduction layer connected to the first conductive pillar, and the second semiconductor structure includes a second conductive pillar and a second conduction layer connected to the second conductive pillar, wherein a material of the first conduction layer and a material of the second conduction layer are conductive material and are volatilizable at a predetermined temperature. Thereafter, the first semiconductor structure and the second semiconductor structure are bonded to combine the first conductive pillar with the second conductive pillar. After the step of bonding the first semiconductor structure and the second semiconductor structure is completed, the first conduction layer and the second conduction layer are disappeared.

This application claims the benefit of Taiwan application Serial No. 113136385, filed Sep. 25, 2024, the subject matter of which is incorporated herein by reference.

### BACKGROUND OF THE INVENTION

### Field of the Invention

The invention relates in general to a method for manufacturing a semiconductor device, and more particularly to a method for manufacturing a three-dimensional semiconductor device.

### Description of the Related Art

As people's demand for semiconductor devices is increasing, even if the transistor size is reduced to the physical limit to improve performance, it may still not be able to meet the needs of future industrial applications. In this regard, researchers are constantly looking for new methods in packaging technology, such as gradually moving advanced packaging technology from a two-dimensional (2D) plane to a three-dimensional (3D) stack, and from a single chip to a multi-chip design. However, in the current bonding process between wafers, there is still a problem of poor bonding of the contacts (such as conductive pillars) between wafers, which may lead to product failure.

### SUMMARY OF THE INVENTION

The invention is directed to improving the bonding between the first semiconductor structure and the second semiconductor structure in the semiconductor device, especially improving the bonding between the conductive layers in the first semiconductor structure and the second semiconductor structure, so that the formed semiconductor device can has good electrical properties.

According to an embodiment of the present invention, a method for manufacturing a semiconductor device is provided. The method includes the following steps. First, a first semiconductor structure and a second semiconductor structure are provided. The first semiconductor structure includes a first conductive pillar and a first conduction layer connected to the first conductive pillar, and the second semiconductor structure includes a second conductive pillar and a second conduction layer connected to the second conductive pillar, wherein a material of the first conduction layer and a material of the second conduction layer are conductive material and are volatilizable at a predetermined temperature. Thereafter, the first semiconductor structure and the second semiconductor structure are bonded to combine the first conductive pillar with the second conductive pillar. After the step of bonding the first semiconductor structure and the second semiconductor structure is completed, the first conduction layer and the second conduction layer are disappeared from the first semiconductor structure and the second semiconductor structure.

Since the surfaces of the first semiconductor structure and the second semiconductor structure are prone to accumulate static charges during the manufacturing process, the static charges can easily affect the probe's determination of the surface topography of the first semiconductor structure and the second semiconductor structure, resulting in the bonding between the first semiconductor structure and the second semiconductor structure may be at risk of failure. The first conduction layer and the second conduction layer in the first semiconductor structure and the second semiconductor structure of the present invention can facilitate the discharge of static charges.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIGS. 1 to 8 illustrate a method for manufacturing a semiconductor device according to an embodiment of the present invention.

FIG. 9 is a comparison diagram illustrating a real surface topography and a surface topography detected by a probe of the first semiconductor structure or the second semiconductor structure of the semiconductor device according to an embodiment of the present invention.

FIG. 10A is a comparison diagram illustrating a real surface topography and a surface topography detected by a probe of the first semiconductor structure or the second semiconductor structure of the semiconductor device according to Comparative Example A of the present invention.

FIG. 10B shows the semiconductor device of Comparative Example A of FIG. 10A.

### DETAILED DESCRIPTION OF THE INVENTION

Various embodiments will be described in more detail below with reference to the accompanying drawings. The narrative content and diagrams are provided for illustration only and are not intended to be limiting. For clarity, some elements and/or symbols may be omitted in some drawings. In addition, elements in the drawings may not be drawn to real scale. It is contemplated that elements and features in one embodiment can be advantageously incorporated into another embodiment without further description.

The present invention provides a method for manufacturing a semiconductor device, which includes bonding a first semiconductor structure and a second semiconductor structure, wherein the first semiconductor structure and the second semiconductor structure respectively include a first conduction layer and a second conduction layer. The first conduction layer and the second conduction layer can prevent static charges from accumulating on the surfaces (such as the bonding surfaces) of the first semiconductor structure and the second semiconductor structure, so the probe can accurately detect the topography of the bonding surfaces of the first semiconductor structure and the second semiconductor structure without being affected by the accumulation of electrostatic charges.

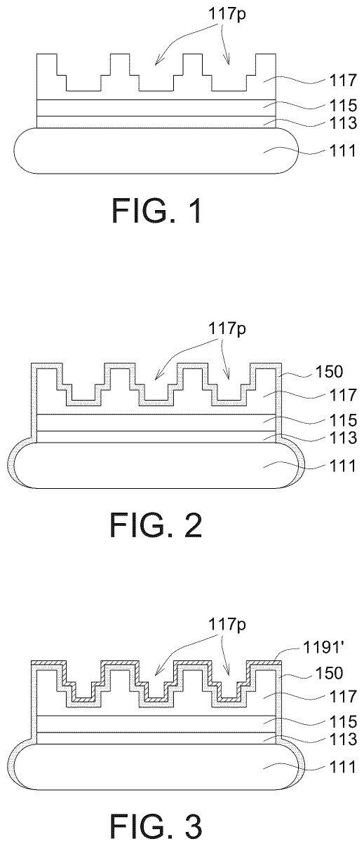

FIGS. 1 to 8 illustrate a method for manufacturing a semiconductor device 10 according to an embodiment of the present invention.

According to an embodiment of the present invention, the method for manufacturing the semiconductor device 10 may include sequential steps as shown in FIGS. 1-8.

Referring to FIG. 1, an initial structure of the first semiconductor structure 110′ is provided, including a first substrate 111 and a first oxide layer 113, a first wiring layer 115 and a first dielectric layer 117 sequentially stacked on the first substrate 111. The first dielectric layer 117 includes a plurality of first openings 117p. According to some embodiments, the material of the first substrate 111 may include silicon, such as a silicon wafer; the material of the first oxide layer 113 may include silicon oxide; the material of the first wiring layer 115 may include a conductive material (such as metal); the material of the first dielectric layer 117 may include dielectric materials, such as silicon oxide (SiOx, wherein x is greater than 0), silicon nitride (SiNx, wherein x is greater than 0), silicon carbonitride (SiCxNy, wherein x is greater than 0, y is greater than 0) or other suitable dielectric materials.

Referring to FIG. 2, a first conduction layer 150 is formed on the initial structure of the first semiconductor structure 110′ as shown in FIG. 1. That is, the first conduction layer 150 covers side surfaces of the first substrate 111, side surfaces of the first oxide layer 113, side surfaces of the first wiring layer 115, side surfaces and an upper surface of the first dielectric layer 117, and side walls of the first openings 117p. It can be seen that the first conduction layer 150 can continuously extend from inside the first opening 117p to outside the first opening 117p, and extend to the first substrate 111. The method of forming the first conduction layer 150 is, for example, a deposition method, such as chemical vapor deposition, physical vapor deposition, etc. According to some embodiments, the material of the first conduction layer 150 includes a conductive material, and the conductive material is volatilizable, such as gasification, at a predetermined temperature, for example, between 300° C. and 1500° C. For example, 500° C. Preferably, the material of the first conduction layer 150 includes carbon element, such as graphene, carbon, diamond-like carbon, carbon nanotube or other suitable carbon structure.

Referring to FIG. 3, a first barrier material layer 1191′ is formed on the first conduction layer 150. The method for forming the first barrier material layer 1191′ is, for example, a deposition method, such as chemical vapor deposition, physical vapor deposition, etc. According to some embodiments, the material of the first barrier material layer 1191′ includes tantalum (Ta), tantalum nitride (TaN), cobalt (Co), ruthenium (Ru), titanium (Ti), titanium nitride (TiN), and others suitable materials or any combination thereof.

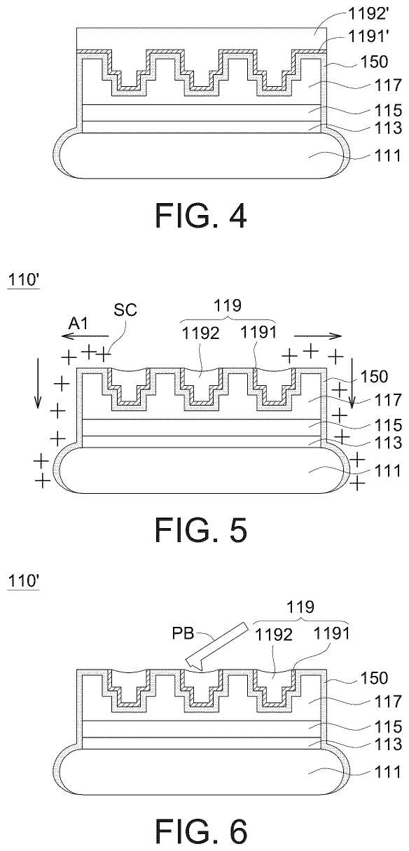

Referring to FIG. 4, a first conductive material layer 1192′ is formed on the first barrier material layer 1191′. The method for forming the first conductive material layer 1192′ is, for example, a deposition method, such as chemical vapor deposition, physical vapor deposition, etc. According to some embodiments, the material of the first conductive material layer 1192′ includes a conductive material (such as a metallic material), such as copper, aluminum, or other suitable conductive materials.

Referring to FIG. 5, a planarization process, such as chemical-mechanical polishing, is performed on the structure as shown in FIG. 4 to remove excess portions of the first barrier material layer 1191′ and the first conductive material layer 1192′. The remaining portions of the first barrier material layer 1191′ and the remaining portions of the first conductive material layer 1192′ respectively form a plurality of first barrier layers 1191 and a plurality of first conductive layers 1192. The first barrier layers 1191 and the first conductive layers 1192 may together form a plurality of first conductive pillars 119. The first conduction layer 150 is connected to (i.e., in electrical contact with) the first conductive pillars 119. The first conduction layer 150 is, for example, connected between the first conductive pillars 119 and the first substrate 111.

The structure as shown in FIG. 5 can be called as a first semiconductor structure 110′. The first semiconductor structure 110′ includes a first substrate 111 and a first oxide layer 113, a first wiring layer 115 and a first dielectric layer 117 sequentially stacked on the first substrate 111. The first dielectric layer 117 includes a plurality of first openings 117p. The first conductive pillars 119 (including the first barrier layers 1191 and the first conductive layers 1192) are formed in the first openings 117p. The first conduction layer 150 is formed between the first dielectric layer 117 and the first conductive pillars 119, is in electrical contact with the first conductive pillars 119, and extends continuously to the first substrate 111.

After the planarization process, a cleaning process can be performed. The cleaning liquid used in the cleaning process includes, for example, hydrofluoric acid (HF). After the cleaning process performed after the planarization process, electrostatic charges SC may be generated on the surfaces of the first barrier layer 1191 and the first conductive layer 1192. The electrostatic charge SC may affect the subsequent detection of the surface topography of the first barrier layer 1191 and the first conductive layer 1192 by the probe PB (detailed below). Since the first conduction layer 150 is in electrical contact with the first barrier layers 1191 of the first conductive pillars 119 (for example, surrounding the first conductive pillars 119 and directly contacting the first barrier layers 1191), the electrostatic charges SC on the surface of the first barrier layers 1191 and the conductive layers 1192 are conducted to the first substrate 111 (as shown by arrow A1), which is similar to the function of grounding, so that the surface topography of the first barrier layer 1191 and the first conductive layer 1192 will not be affected by the electrostatic charges SC and a misjudgment will not be generated.

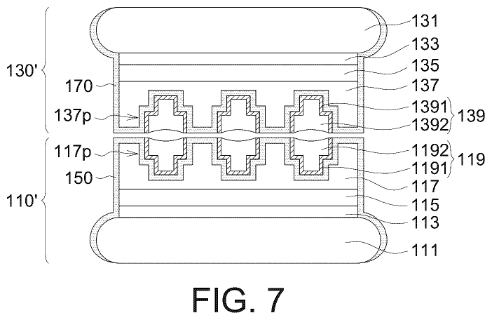

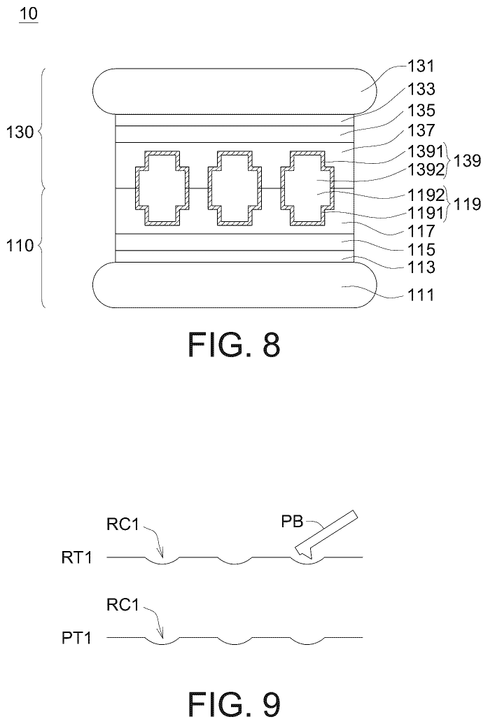

Please refer to FIG. 6. After the cleaning process is completed, the surface topography of the first semiconductor structure 110′ as shown in FIG. 5 (such as the surface topography of the first barrier layers 1191 and the first conductive layer 1192) is detected by the probe PB. 1192) to facilitate subsequent bonding of the first conductive pillars 119 and the second conductive pillars 139 (as shown in FIGS. 7-8) (detailed below). The probe PB is, for example, a probe used in an atomic force microscope (AFM).

Referring to FIG. 7, a second semiconductor structure 130′ is provided, and the first semiconductor structure 110′ and the second semiconductor structure 130′ are bonded. The second semiconductor structure 130′ may be formed simultaneously with the first semiconductor structure 110′, or may be formed before or after the first semiconductor structure 110′ is formed.

The formation method and structure of the second semiconductor structure 130′ may be the same or similar to the formation method and structure of the aforementioned first semiconductor structure 110′, and will not be described in detail here. Similarly, the second semiconductor structure 130′ includes a second substrate 131 and a second oxide layer 133, a second wiring layer 135 and a second dielectric layer 137 sequentially stacked on the second substrate 131. The second dielectric layer 137 includes a plurality of second openings 137p. The second conductive pillars 139 (including the second barrier layer 1391 and the second conductive layer 1392) are formed in the second opening 137p. The materials, structures, and functions of the second substrate 131, the second oxide layer 133, the second wiring layer 135, the second dielectric layer 137, the second conductive pillars 139 (including the second barrier layers 1391 and the second conductive layers 1392) and the first conduction layer 150 may be the same as the materials, structures, and functions of the first substrate 111, the first oxide layer 113, the first wiring layer 115, the first dielectric layer 117, the first conductive pillars 119 (including the first barrier layers 1191 and the first conductive layers 1192) and the second conduction layer 170. That is, the second conduction layer 170 is formed between the second dielectric layer 137 and the second conductive pillar 139, is in electrical contact with the second conductive pillars 139, and extends continuously to the second substrate 131. Since the second conduction layer 170 is in electrical contact with the second barrier layers 1391 of the second conductive pillars 139 (for example, surrounding the second conductive pillars 139 and directly contacting the second barrier layers 1391), the electrostatic charge SC on the surface of the second barrier layers 1191 and the second conductive layers 1192 are conducted to the second substrate 131, similar to the function of grounding, so that the surface topography of the second barrier layers 1391 and the second conductive layers 1392 will not be affected by the electrostatic charges SC, and a misjudgment will not be generated.

The bonding method of the first semiconductor structure 110′ and the second semiconductor structure 130′ is, for example, a hybrid bonding process (the present invention is not limited thereto), and may include a thermal treatment, such as an annealing process. For example, the first semiconductor structure 110′ and the second semiconductor structure 130′ are aligned face to face, so that the first conductive pillars 119 corresponds to the second conductive pillars 139 (the positions are the same as each other). Secondly, the first conduction layer 150 and the second conduction layer 170 are gasified and disappeared at the same time through the annealing process, and the first conductive pillars 119 and the second conductive pillars 139 are combined with each other to form the semiconductor device 10 as shown in FIG. 8. For example, the annealing process includes a predetermined temperature (for example, 500° C.). When reaching the predetermined temperature (or greater than the predetermined temperature), the first conduction layer 150 and the second conduction layer 170 are volatilizable, and are gasified, and then are completely disappeared from the first semiconductor structure 110′ and the second semiconductor structure 130′.

Referring to FIG. 8, the first conduction layer 150 and the second conduction layer 170 in the first semiconductor structure 110′ and the second semiconductor structure 130′ are removed during the annealing process as sacrificial layers to form the semiconductor device 10 in which the first semiconductor structure 110 and the second semiconductor structure 130 are combined with each other. In the semiconductor device 10, the first dielectric layer 117 and the first conductive pillars 119 (including the first barrier layers 1191 and the first conductive layers 1192) are tightly combined with the second dielectric layer 137 and the second conductive pillars 139 (including second barrier layers 1391 and second conductive layers 1392), respectively. In other words, after the step of bonding the first semiconductor structure 110′ and the second semiconductor structure 130′ is completed, the first conduction layer 150 and the second conduction layer 170 are disappeared (i.e. gasified) from the first semiconductor structure 110′ and the second semiconductor structure 130′, and do not exist in the first semiconductor structure 110 and the second semiconductor structure 130. That is, when the materials of the first conduction layer 150 and the second conduction layer 170 include carbon atoms (or consist essentially of carbon atoms), carbon atoms do not exist in the interface region between the first semiconductor structure 110 and the second semiconductor structure 130. The first dielectric layer 117, the second dielectric layer 137, the first barrier layers 1191 and the second barrier layers 1391 also do not contain carbon atoms from the first conduction layer 150 and the second conduction layer 170.

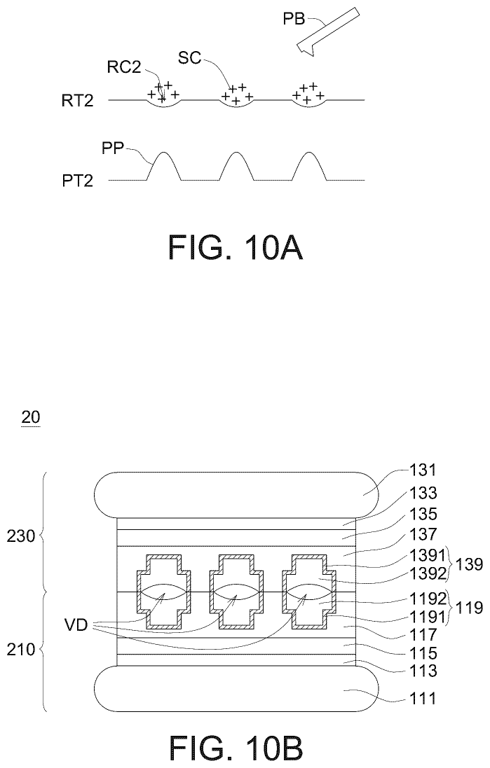

FIG. 9 illustrates a comparison diagram between the real surface topography and the surface topography detected by the probe of the first semiconductor structure 110 or the second semiconductor structure 130 of the semiconductor device 10 according to an embodiment of the present invention. FIG. 10A shows a comparison diagram between the real surface morphology and the surface topography detected by the probe of the first semiconductor structure or the second semiconductor structure of the semiconductor device 20 according to Comparative Example A of the present invention. FIG. 10B illustrates the semiconductor device 20 of Comparative Example A of FIG. 10A.

Please refer to FIG. 9. According to the above embodiment (i.e. the embodiment shown in FIGS. 1 to 8), the real surface morphology of the first semiconductor structure 110′ and the second semiconductor structure 130′ is shown as RT1, the surface topography of the first semiconductor structure 110′ and the second semiconductor structure 130′ detected by the probe PB is shown as PT1. It can be seen that the surface topography PT1 detected by the probe PB is consistent with the real surface topography. RT1. For example, the recesses RC1 corresponding to the first conductive layer 1192 or the second conductive layer 1391 can be truly reflected, so the first semiconductor structure 110′ and the second semiconductor structure 130′ can be well bonded.

Please refer to FIG. 10A. According to a Comparative Example A, the first semiconductor structure 210 and the second semiconductor structure 230 are similar to the first semiconductor structure 110′ and the second semiconductor structure 130′ respectively. The difference between the first semiconductor structure 210 and the second semiconductor structure 230 and the first semiconductor structure 110′ and the second semiconductor structure 130′ is in that the first semiconductor structure 210 does not include the first conduction layer 150 and the second semiconductor structure 230 does not include the second conduction layer 170. The real surface topography of the first semiconductor structure 210 and the second semiconductor structure 230 of Comparative Example A is shown as RT2. The surface topography of the first semiconductor structure 210 and the second semiconductor structure 230 detected by the probe PB is shown as PT2. It can be seen that the surface topography PT2 detected by the probe PB is not consistent with the real surface topography RT2. For example, the surface topography PT2 of the recesses RC2 in the first conductive layer 1192 or the second conductive layer 1391 are affected by the electrostatic charges SC, the probe PB misjudges the recesses RC2 as protruding portions PP.

Referring to FIG. 10B, due to the misjudgment of probe PB in Comparative Example A, the bonding between the first semiconductor structure 210 and the second semiconductor structure 230 is failed, and voids VD are generated between the first conductive layer 1192 and the second conductive layer 1392, causing the semiconductor device 20 to fail.

According to the above description, the method for manufacturing the semiconductor device of the present invention includes forming a first conduction layer and a second conduction layer in the first semiconductor structure and the second semiconductor structure respectively, and the material of the first conductive layer and the second conductive layer are a conductive material and is volatilizable at a predetermined temperature. During the fabrication of the first semiconductor structure and the second semiconductor structure (for example, during the cleaning process after the planarization process), static charges will be generated on the surface of the first semiconductor structure and the surface of the second semiconductor structure. The conduction layer and the second conduction layer can conduct the electrostatic charges on the surface of the first semiconductor structure and the surface of the second semiconductor structure, so the electrostatic charges will not accumulate on the surface of the first semiconductor structure and the surface of the second semiconductor structure. The static charges will not affect the detection of the first semiconductor structure surface and the second semiconductor structure surface by the probe. For example, the probe can more accurately determine the surface topography of the first conductive layer in the first semiconductor structure and the second conductive layer in the second semiconductor structure, which can help the first semiconductor structure and the second semiconductor structure to be successfully bonded, so that the first conductive layers can be tightly combined with the second conductive layers. The risk of bonding failure between the first semiconductor structure and the second semiconductor structure can be greatly reduced, and the resulting semiconductor structure can have good electrical properties.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for manufacturing a semiconductor device, comprising:
providing a first semiconductor structure and a second semiconductor structure, the first semiconductor structure comprising a first conductive pillar and a first conduction layer connected to the first conductive pillar, and the second semiconductor structure comprising a second conductive pillar and a second conduction layer connected to the second conductive pillar, wherein a material of the first conduction layer and a material of the second conduction layer are conductive material and are volatilizable at a predetermined temperature; and
bonding the first semiconductor structure and the second semiconductor structure to combine the first conductive pillar with the second conductive pillar, wherein, after the step of bonding the first semiconductor structure and the second semiconductor structure is completed, the first conduction layer and the second conduction layer are disappeared from the first semiconductor structure and the second semiconductor structure.

2. The method according to claim 1, wherein the step of bonding the first semiconductor structure and the second semiconductor structure comprises an annealing process, and the annealing process comprises the predetermined temperature.

3. The method according to claim 2, wherein the predetermined temperature is between 300° C. and 1500° C.

4. The method according to claim 2, wherein the first conduction layer and the second conduction layer are gasified and disappeared at a same time through the annealing process to combine the first conductive pillar with the second conductive pillar.

5. The method according to claim 1, wherein a method for bonding the first semiconductor structure and the second semiconductor structure is a hybrid bonding process.

6. The method according to claim 1, wherein a material of the first conduction layer and the second conduction layer comprises a carbon element.

7. The method according to claim 6, wherein the material of the first conduction layer and the second conduction layer comprises graphene.

8. The method according to claim 1, wherein the first semiconductor structure further comprises a first substrate and a first dielectric layer stacked on the first substrate, wherein the first dielectric layer comprises a first opening, the first conductive pillar is formed in the first opening, and the first conduction layer is in electrical contact with the first conductive pillar and extends continuously to the first substrate; and
the second semiconductor structure further comprises a second substrate and a second dielectric layer stacked on the second substrate, wherein the second dielectric layer comprises a second opening, and the second conductive pillar is in electrical contact with the second conductive pillar and extends continuously to the second substrate.

9. The method according to claim 8, wherein the first conduction layer extends continuously from inside the first opening to outside the first opening, and the second conduction layer extends continuously from inside the first opening to outside the second opening.

10. The method according to claim 8, wherein the first conduction layer is formed between the first dielectric layer and the first conductive pillar, and the second conduction layer is formed between the second conductive pillar and the second dielectric layer.

11. The method according to claim 8, wherein the method for forming the first conductive pillar further comprises:
forming a first barrier material layer on the first conduction layer;
forming a first conductive material layer on the first barrier material layer; and
performing a planarization process to remove excess portions of the first barrier material layer and the first conductive material layer, and a remaining portion of the first barrier material layer and a remaining portion of the first conductive material layer forming a first barrier layer and a first conductive layer respectively, the first barrier layer and the first conductive layer together forming the first conductive pillar.

12. The method according to claim 11, wherein, after the planarization process, a cleaning process is performed, and a cleaning liquid used in the cleaning process comprises hydrofluoric acid.

13. The method according to claim 11, further comprising detecting a surface topography of the first semiconductor structure through a probe.

14. The method according to claim 1, wherein, after the step of bonding the first semiconductor structure and the second semiconductor structure is completed, no carbon atoms exist in an interface region between the first semiconductor structure and the second semiconductor structure.
